(19) United States
(12) Patent Application Publication
(10) Pub. No.: US 2015/0194196 A1
(43) Pub. Date: Jul. 9, 2015

(54) MEMORY SYSTEM WITH HIGH PERFORMANCE AND HIGH POWER EFFICIENCY AND CONTROL METHOD OF THE SAME

(71) Applicant: Sunplus Technology Co., Ltd., Hsinchu (TW)

(72) Inventors: Ming-Chuan Huang, Hsinchu County (TW); Han-Jung Huang, Yunlin County (TW); Chih-Hao Cheng, Tainan City (TW); Chen-Hsiang Ma, Kaohsiung City (TW)

(73) Assignee: Sunplus Technology Co., Ltd., Hsinchu (TW)

(21) Appl. No.: 14/150,780

(22) Filed: Jan. 9, 2014

(51) Int. Cl. G11C 7/10

(52) U.S. Cl. CPC G11C 7/1072

(57) ABSTRACT

A memory control system has an SDRAM device, a memory controller, a loading monitoring unit and a memory physical module. The SDRAM device has a plurality of SDRAM cells for storing data. The loading monitoring unit detects workload of a memory interface of the SDRAM device. The memory controller switches an operation condition of the memory system from a first condition to a second condition when the detected workload satisfies at least one predetermined criterion. The memory physical module is coupled between the SDRAM device and the memory controller and has an interface timing calibration circuit configured to adjust timing of signals of the memory interface such that the signals are adjusted in best timing location and data are captured with a great timing margin.

### BACKGROUND OF THE INVENTION

1. Field of the Invention

The present invention is related to a memory system and a control method thereof.

2. Description of the Prior Art

SDRAM devices are characterized by having AC timing parameters. Examples are refresh interval (maximum time between two refresh commands must be issued to the SDRAM), CAS latency (minimum time of the data becomes available (output by SDRAM) after SDRAM receiving a read command).

These AC parameters are coded in clock cycles assuming a known and constant memory clock frequency and they are typically programmed to the memory controller during the power on initialization stage. This was sufficient in the old days when the memory frequency was set once during initialization and has never changed since then. For modern battery operated devices power consumption is a critical technical and marketing requirement. A widely used technique for power reducing is dynamic voltage and frequency scaling (DVFS).

Scaling of the clock frequency and voltages used for memory accesses requires updating the AC parameters of the memory controller because the AC parameters are typically coded in a clock cycle-base. Owing to long latencies in such updating when scaling frequency and/or voltage, the DVFS algorithm is conservative since the costs of misprediction are high. Conservative DVFS algorithms therefore are less power efficient.

### SUMMARY OF THE INVENTION

As discussed below in the claims, a memory control system has an SDRAM, a memory controller, a loading monitor and a memory module. The loading monitor detects workload of a memory interface of the SDRAM, the memory controller switches the memory operation condition, and data are captured with a great timing margin.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a functional block diagram of a memory system.

FIG. 2 is a functional block diagram of an interface timing calibration circuit of the memory system in FIG. 1.

FIG. 3 is a flow chart of a control method of the memory system in FIG. 1.

FIG. 4 is a flow chart of a control method of the memory system in FIG. 1 according to another embodiment of the present invention.

FIG. 5 is a flow chart of performing power-up initialization procedures and trimming procedures according to an embodiment of the present invention.

### DETAILED DESCRIPTION

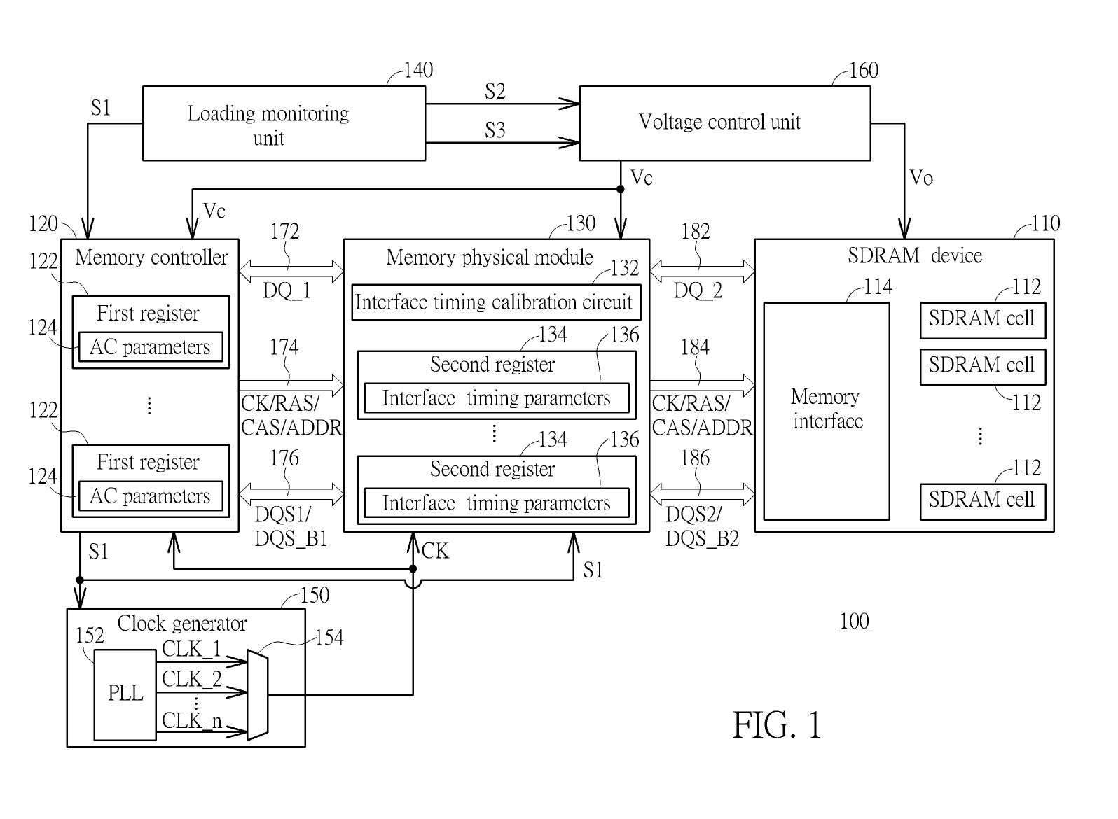

FIG. 1 is a functional block diagram of a memory system 100 according to an embodiment of the present invention. The memory system 100 is essentially used as a data storage device for an electronic apparatus (e.g. a mobile phone or a computer system, etc.). The memory system 100 has an SDRAM device 110, a memory controller 120 and a memory physical module 130. The memory controller 120 and the memory physical module 130 are applied with an operation voltage Vc, and the SDRAM device 110 is applied with an SDRAM operating voltage Vo. The SDRAM device 110 has a plurality of SDRAM cells 112, each of which is configured to storing at least one bit of data. The memory controller 120 is configured to access (e.g. read and write) the SDRAM device 110. Upon the SDRAM interface standard, multiple control signals are used to perform the access operations of the SDRAM device 110, and the used control signals include an operating clock (CK), row address strobe (RAS), column address strobe (CAS), address bus signals (ADDR), data strobe signals (DQS2/DQS_B2), etc. The memory physical module 130 is coupled between the memory controller 120 and the SDRAM device 110 and is configured to process data signals (e.g. DQ_1 and DQ_2), the control signals (e.g. CK/RAS/CAS/ADDR) and data strobe signals (e.g. DQS1/DQS_B1 and DQS2/DQS_B2) transmitted between the memory controller 120 and the SDRAM device 110.

The data transmission of the SDRAM device 110 is essentially relied on the operating clock CK and the data strobe signals (DQS2/DQS_B2) as a reference to complete signal synchronization (e.g. synchronous latch and transmission of data). The data strobe signals DQS1/DQS_B1 on a strobe bus 176 are differential and complementary, and the data strobe signals DQS2/DQS_B2 on a strobe bus 186 are differential and complementary. The data strobe signals DQS2/DQS_B2 are control signals allowing a data receiver (e.g. the memory controller 120 or the SDRAM device 110) to latch data from the data signal DQ_2 on a data bus 182. Typically, the data buses 182 are 8-bit data buses.

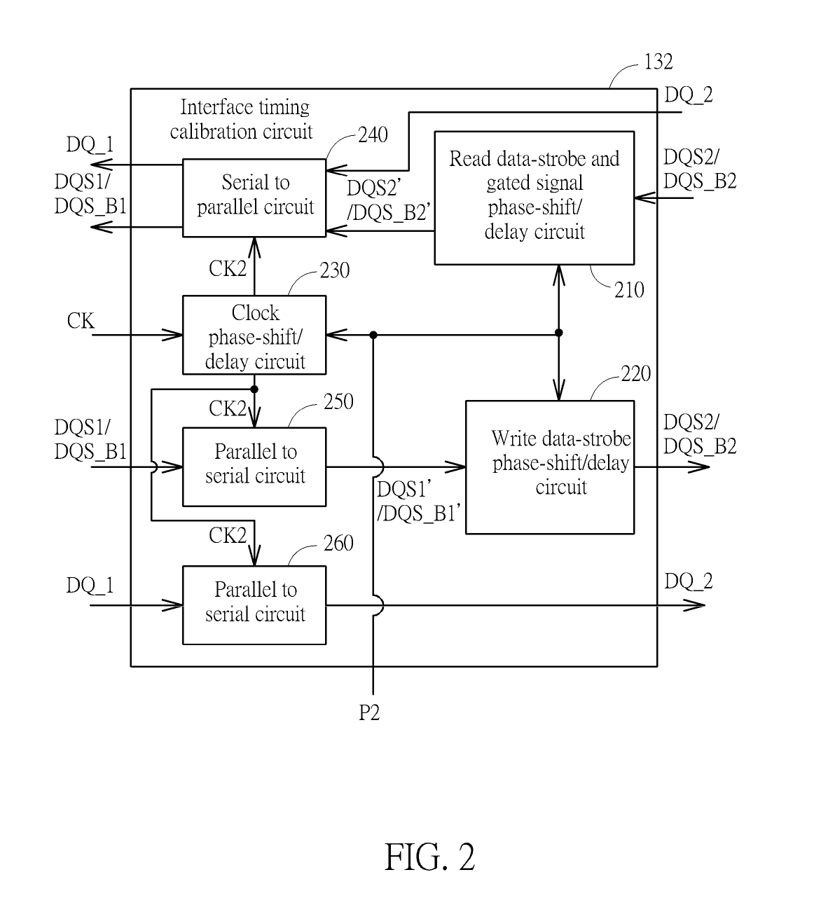

FIG. 2 is a functional block diagram of an interface timing calibration circuit 132 of the memory physical module 130 of the memory system 100 in FIG. 1. The interface timing calibration circuit 132 of the memory physical module 130 is configured to calibrate timing of data signals DQ_2 and data strobe signals DQS2/DQS_B2 of the SDRAM device 110 by performing an interface timing training process according to a selected set of AC parameters 124 and a selected set of interface timing parameters 136 (or P2). During a read operation of the memory system 100, the memory controller 120 issues a serial of command (pre-charge, active and read) to the memory physical module 130 via a first bus 174, and after a plurality of cycles of the operating clock CK, the SDRAM device 110 outputs the data signal DQ_2 and the data strobe signals DQS2/DQS_B2 to the memory physical module 130 via the data bus 182 and the strobe bus 186 based on the timing specification of the SDRAM device 110 (e.g. JEDEC standard of DDR, DDR2, DDR3 or DDR4 SDRAM). The memory physical module 130 will transfer the control signals CK/RAS/CAS/ADDR from the second bus 184 to the first bus 174. Moreover, the memory physical module 130 converts the data signal DQ_2 and data strobe signals DQS2/DQS_B2 into the data signal DQ_1 and data strobe signals DQS1/DQS_B1 respectively, and then outputs the data signal DQ_1 and data strobe signals DQS1/DQS_B1 to the memory controller 120, such that the memory controller 120 would obtain the read data by strobing the data signal DQ_1 according to the data strobe signals DQS1/DQS_B1.

The data signal DQ_2 and the data strobe signals DQS2/DQS_B2 are serial signals, and the interface timing calibration circuit 132 has a read data-strobe and gated signal phase-shift/delay circuit 210, a write data-strobe phase-shift/delay circuit 220, a clock phase-shift/delay circuit 230, a serial to parallel circuit 240 and parallel to serial circuits 250 and 260. The interface timing calibration circuit 132 receives the selected set of interface timing parameters P2. The clock phase-shift/delay circuit 230 is configured to phase shift and/or delay the clock signal CK according to the selected set of interface timing parameters P2 so as to output a clock signal CK2 to the serial to parallel circuit 240 and parallel to serial circuits 250 and 260. The read data-strobe and gated signal phase-shift/delay circuit 210 is configured to phase shift and/or delay the data strobe signals DQS2/DQS_B2 according to the selected set of interface timing parameters P2 so as to output data strobe signals DQS2′/DQS_B2′. The data strobe signals DQS2′/DQS_B2′ are serial signals, and the serial to parallel circuit 240 coverts the data strobe signals DQS2′/DQS_B2′ into the data strobe signals DQS1/DQS_B1 according to the clock signal CK2, where the data strobe signals DQS1/DQS_B1 are parallel signals.

During a write operation of the memory system 100, the memory controller 120 issues a serial of command (pre-charge, active and write) to the memory physical module 130 and then transmits the control signals CK/RAS/CAS/ADDR, the data signal DQ_1 and the data strobe signals DQS1/DQS_B1 through the data bus 172, the first bus 174 and the strobe bus 176 respectively to the memory physical module 130. The memory physical module 130 will transfer the control signals CK/RAS/CAS/ADDR from the first bus 174 to the second bus 184. Moreover, the memory physical module 130 converts the data signal DQ_1 and data strobe signals DQS1/DQS_B1 into the data signal DQ_2 and data strobe signals DQS2/DQS_B2 respectively, and then outputs the data signal DQ_2 and data strobe signals DQS2/DQS_B2 to the SDRAM device 110, such that the SDRAM device 110 would obtain the write data by strobing the data signal DQ_2 according to the data strobe signals DQS2/DQS_B2 and then write the write data into the SDRAM cells 112.

The data signal DQ_1 and the data strobe signals DQS1/DQS_B1 are parallel signals. The parallel to serial circuit 250 coverts the data strobe signals DQS1/DQS_B1 into the data strobe signals DQS1′/DQS_B1′ according to the clock signal CK2, and the parallel to serial circuit 260 coverts the data signal DQ_1 into the data signal DQ_2 according to the clock signal CK2. The write data-strobe phase-shift/delay circuit 220 is configured to phase shift and/or delay the data strobe signals DQS1′/DQS_B1′ according to the selected set of interface timing parameters P2 so as to output the data strobe signals DQS2/DQS_B2 to the SDRAM device 110.

Due to a transistor's operation time, a transmission line's propagation/transition delay and the like, interface timing delays of the data signals DQ_1 and DQ_2 and the data strobe signals DQS1/DQS_B1 and DQS2/DQS_B2 occur. Accordingly, AC parameters and interface timing parameters of the memory system 100 should be set properly so as to accurately latch data on the data buses 172 and 182 and surely obtain the stability and reliability of the memory system 100.

In an embodiment of the present invention, the memory controller 120 comprises a plurality of first registers 122, and the memory physical module 130 comprises a plurality of second registers 134. Each of the first registers 122 is configured to store a set of AC parameters 124, and each of the second registers 134 is configured to store a set of interface timing parameters 136. The sets of AC parameters 124 and the sets of interface timing parameters 136 are coded in clock cycles of the operating clock CK. When the memory system 100 operates, one of the sets of AC parameters 124 and one of the sets of interface timing 136 are selected, and the memory system 100 operates according to the selected set of AC parameters 124 and selected set of interface timing parameters 136. Accordingly, the memory system 100 may operate in different conditions (e.g. with different operating frequencies and/or voltages) according to different combinations of the selected sets of AC parameters 124 and interface timing parameters 136. For instance, the memory system 100 may operate in a first condition according to a first set of the sets of AC parameters 124 and a first set of the sets of the interface timing parameters 136, and may operate in a second condition according to a second set of the sets of AC parameters 124 and a second set of the sets of the interface timing parameters 136.

Further, the sets of AC parameters 124 are configured to set the memory controller 120, such that the memory controller 120 can operates in different states (e.g. with different operating frequencies and/or voltages) based on the sets of AC parameters 124. Examples of the AC parameters 124 are refresh interval (maximum time between two refresh commands must be issued to the memory) and CAS latency (minimum time of the data becomes available after issuing a read command). The definition of the AC parameters 124 are described in more detail in the memory specification (e.g. JEDEC standard of DDR, DDR2, DDR3 or DDR4 SDRAM).

In an embodiment of the present invention, when initializing the memory system 100, a plurality of power-up initialization procedures and trimming procedures are performed. Each of the power-up initialization procedures may be executed by following the steps defined in the power-up initialization sequence of the memory specification. In addition, before each power-up initialization procedure, a corresponding set of AC parameters 124 is selected from the first registers 122, and the memory controller 120 adjusts the settings of the frequency of the operating clock CK, the voltage level of the operation voltage Vc and/or the voltage level of the SDRAM operating voltage Vo according to the selected set of AC parameters 124. Once a power-up initialization procedure is finished, one of the trimming procedures is performed sequentially. Each of the trimming procedures may be executed by the interface timing calibration circuit 132 of the physical module 130 to generate one of the sets of interface timing parameters 136 according to a corresponding set of AC parameters 124. After the trimming procedures are finished, the sets of interface timing parameters 136 generated by the interface timing calibration circuit 132 are stored in the second registers 134.

The sets of interface timing parameters 136 are configured to set the memory physical module 130, such that the data signals (e.g. DQ_1 and DQ_2) and the control signals (e.g. CK/RAS/CAS/ADDR, DQS1/DQS_B1 and DQS2/DQS_B2) could be processed (i.e. delayed and/or phase shifted) properly when the operating condition of the memory system 100 is switched. Consequently, the memory controller 120 and the SDRAM device 110 can correctly latched the data on the data buses 172 and 182 by strobing the data signals DQ_1 and DQ_2 based on the properly-processed data strobe signals DQS1/DQS_Q1 and DQS2/DQS_Q2.

The memory system 100 further comprises a memory interface 114 configured to transform the data signals and the control signals between the memory physical module 130 and the SDRAM device 110. The memory interface 114 may be integrated with the memory physical module 130 or the SDRAM device 110. In the embodiment of FIG. 1, the memory interface 114 is integrated with the SDRAM device 110. In another embodiment of the present invention, the memory interface 114 is integrated with memory physical module 130.

In an embodiment of the present invention, the memory system 100 further comprises a loading monitoring unit 140 configured to detect workload of the memory interface 114 or the memory physical module 130 and generate a first selection signal S1 according to the detected workload of the memory interface 114 or the memory physical module 130. The memory controller 120 is further configured to switch the operation condition of the memory system 100 from the first condition to the second condition when the detected workload of the memory interface 114 or the memory physical module 130 satisfies at least one predetermined criterion. In an embodiment of the present invention, the least one predetermined criterion is set manually and programmed to the loading monitoring unit 140. However, the present invention is not limited thereto.

Moreover, in an embodiment of the present invention, the loading monitoring unit 140 may be coupled to the data bus 172 or 182 such that the workload is detected by the loading monitoring unit 140 according to amount of data transmitted on the bus 172 or 182. In another embodiment of the present invention, the loading monitoring unit 140 may be a built-in hardware of the memory controller 120, and the loading monitoring unit 140 detects the workload by calculating amount of data that the memory controller 120 transmits to the memory physical module 130 and receives from the memory physical module 130. In an embodiment of the present invention, the loading monitoring unit 140 may be an application (i.e. software or firmware) executed by the memory controller 120, a CPU or a microprocessor.

Referring to FIG. 1, the first selection signal S1 is transmitted to the memory controller 120 and the memory physical module 130, such that the memory controller 120 selects one of the sets of AC parameters 124 from the first registers 122 according to a value of the first selection signal S1, and the memory physical module 130 selects one of the sets of interface timing parameters 136 from the second registers 134 according to the value of the first selection signal S1. Accordingly, based on the detected workload of the memory interface 114 or the memory physical module 130, the timing of the signals of the memory controller 120 and the memory physical module 130 are properly set according to the selected set of AC parameters 124 and the selected set of interface timing parameters 136. Since the selected set of AC parameters 124 and the selected set of interface timing parameters 136 are used to set the memory system 100, it is unnecessary to retrain the SDRAM device 110 during switching the operation condition of the memory system 100 to obtain proper interface timing parameters other than the sets of interface timing parameters 136 stored in the second registers 134. Accordingly, the latency in such updating of timing parameters (i.e. the AC parameters 124 and the interface timing parameters 136) of the memory system. 100 when scaling the frequency and/or voltage level of the memory system 100 is small, such that the memory system 100 can effectively finish dynamic voltage and frequency scaling (DVFS) operation.

In an embodiment of the present invention, the memory system 100 may further comprises a clock generator 150 coupled to the memory controller 120. The clock generator 150 is configured to generate a plurality of reference clocks CLK_1 to CLK_n with different frequencies, and to output the operating clock CK of the memory system 100 by selecting a reference clock from the reference clocks CLK_1 to CLK_n according to the first selection signal S1. Accordingly, when the operation condition of the memory system 100 is switched from the first condition to the second condition, the operating frequency of the operating clock CK is switched from a first frequency to a second frequency, where the first frequency is different from the second frequency. For example, when the memory system 100 is switched from DDR3-800 mode to DDR3-1600 mode, the operating frequency of operating clock CK is switched from 400 MHz to 800 MHz. In an embodiment of the present invention, the clock generator 150 comprises a phase-locked loop (PLL) circuit 152 and a multiplexer 154. The PLL circuit 152 generates the reference clocks CLK_1 to CLK_n, and the multiplexer 154 selects the operating clock CK from the reference clocks CLK_1 to CLK_n according to the first selection signal S1 (i.e. a clock selection signal).

In an embodiment of the present invention, the memory system 100 may further comprises a voltage control unit 160 coupled to the loading monitoring unit 140. The loading monitoring unit 140 outputs a core-voltage selection signal S2 and an SDRAM-operating-voltage selection signal S3 according to the detected workload of the memory interface 114 or the memory physical module 130. The voltage control unit 160 may adjust the voltage levels of the operation voltage Vc and the SDRAM operating voltage Vo according to the selection signals S2 and S3. Accordingly, when the operation condition of the memory system 100 is switched from the first condition to the second condition, the operation voltage Vc is switched from a first voltage to a second voltage and/or the SDRAM operating voltage Vo is switched from a third voltage to a fourth voltage, where the first voltage is different from the second voltage, and the third voltage is different from the fourth voltage.

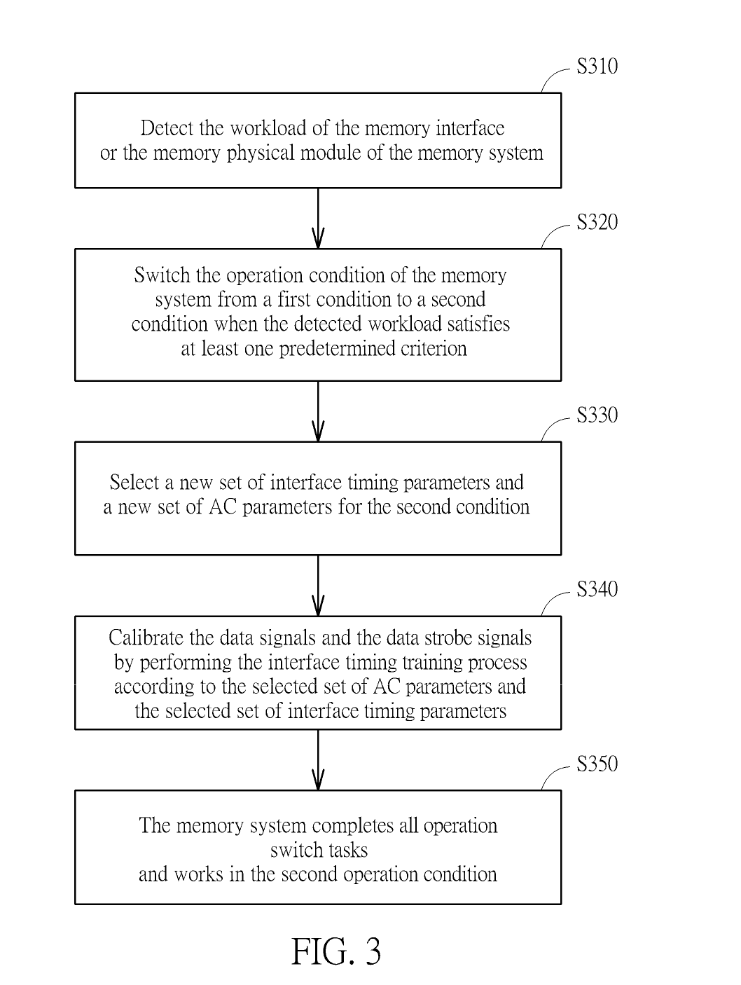

FIG. 3 is a flow chart of a control method of the memory system 100 according to an embodiment of the present invention. The control method illustrated in FIG. 3 comprises the following steps:

S310: detect the workload of the memory interface 114 or the memory physical module 130 of the memory system 100;

S320: switch the operation condition of the memory system 100 from a first condition to a second condition when the detected workload of the memory interface 114 or the memory physical module 130 satisfies at least one predetermined criterion;

S330: select a new set of interface timing parameters and a new set of AC parameters for the second condition;

S340: calibrate the data signals and the data strobe signals by performing the interface timing training process according to the selected set of AC parameters and the selected set of interface timing parameters; and

S350: the memory system completes all operation switch tasks and works in the second operation condition (i.e. a new operation condition).

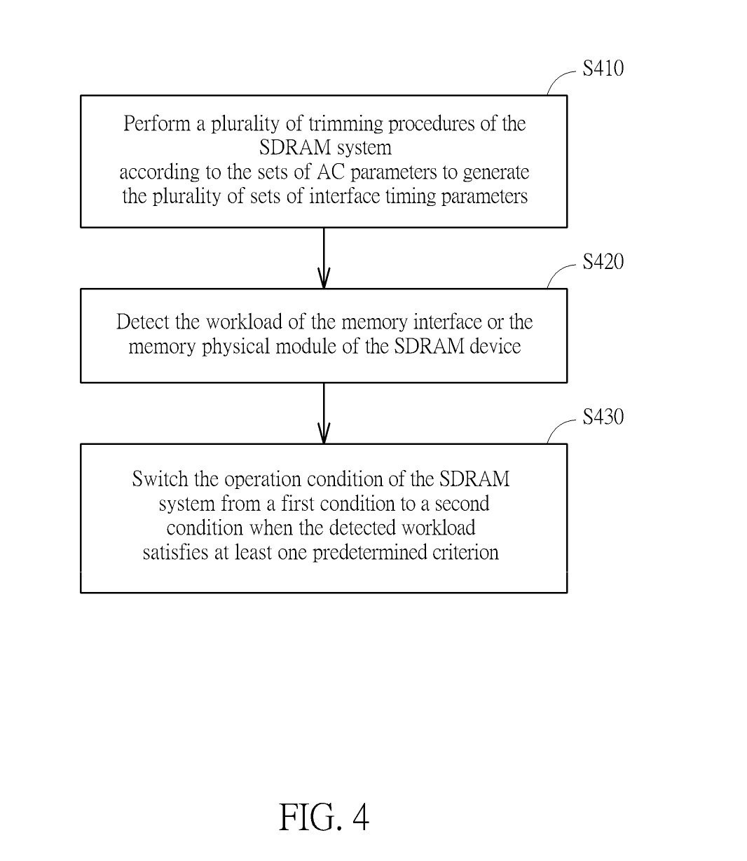

FIG. 4 is a flow chart of a control method of the memory system 100 according to another embodiment of the present invention. The control method illustrated in FIG. 4 comprises the following steps:

S410: perform a plurality of trimming procedures of the memory system 100 according to the sets of AC parameters 124 to generate the plurality of sets of interface timing parameters 136;

S420: detect the workload of the memory interface 114 or the memory physical module 130 of the SDRAM device 110; and

S430: switch the operation condition of the memory system 100 from a first condition to a second condition when the detected workload of the memory interface 114 satisfies at least one predetermined criterion.

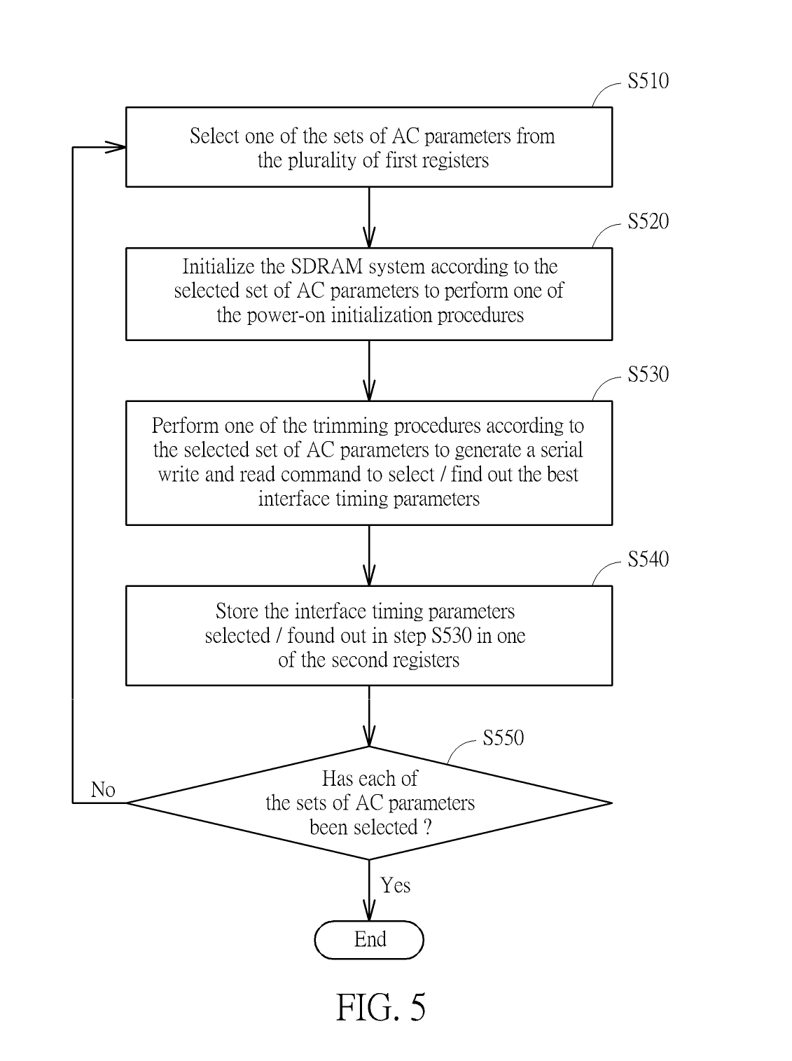

Please refer to FIG. 5, which is a flow chart of performing the foresaid power-up initialization procedures and trimming procedures according to an embodiment of the present invention. The sequence of performing the power-up initialization procedures and trimming procedures includes the following steps:

S510: select one of the sets of AC parameters 124 from the plurality of first registers 122;

S520: initialize the SDRAM device 110 according to the selected set of AC parameters 124 to perform one of the power-up initialization procedures;

S530: perform one of the trimming procedures according by the selected AC parameters 124 to generate a serial read and write commands to select/get the best interface timing parameters 136;

S540: store the set of interface timing parameters 136 generated in step S530 in one of the second registers 134; and

S550: determine whether each of the sets of AC parameters 124 has been selected to perform the step S510; if the result is positive, then the initialization of the SDRAM device 110 is finished; otherwise, step S510 is repeated.

In summary, the present invention provides a memory system and a control method of the memory system. During initialization of the memory system, a plurality of trimming procedures of SDRAM device are performed according to sets of AC parameters and sets of interface timing parameters. The plurality of sets of AC parameters are stored in first registers, and the sets of interface timing parameters are stored in second registers. When the operation condition of the memory system is switched, one of the sets of AC parameters is selected from the first registers, and one of the sets of interface timing parameters is selected from the second registers. Since the selected set of AC parameters and the selected set of interface timing parameters are used to set the memory system immediately, it is unnecessary to retrain the memory system to obtain proper interface timing parameters because the interface timing parameters have been stored in the second registers. Accordingly, the latency in such updating of timing parameters (i.e. the AC parameters and the interface timing parameters) of the memory system when scaling frequency and/or voltage of the memory system is shorter, such that the memory system can effectively finish dynamic voltage and frequency scaling (DVFS) to grain best system performance and reduce power consumption.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A control method of a memory system, comprising:
detecting workload of a memory interface of the memory system;
switching an operation condition of the memory system from a first condition to a second condition when the detected workload of the memory interface satisfies at least one predetermined criterion;
selecting a set of AC parameters and a set of interface timing parameters for the second condition; and
calibrating timing of data signals and data strobe signals of a SDRAM device of the memory system by performing an interface timing training process according to the selected set of AC parameters and the selected set of interface timing parameters.

2. The control method of claim 1, wherein switching the operation condition of the memory system from the first condition to the second condition comprises switching an operating frequency of the memory system from a first frequency to a second frequency.

3. The control method of claim 1, wherein switching the operation condition of the memory system from the first condition to the second condition comprises switching an operation voltage of a memory controller and a memory physical module of the memory system from a first voltage to a second voltage and/or switching an SDRAM operating voltage of the SDRAM device from a third voltage to a fourth voltage.

4. The control method of claim 1, wherein switching the operation condition of the memory system from the first condition to the second condition comprises:
initializing the SDRAM device according to the selected set of AC parameters and the selected set of interface timing parameters.

5. A memory system, comprising:
an SDRAM device, comprising a plurality of SDRAM cells configured to store data;
a memory controller, configured to switch an operation condition of the memory system from a first condition to a second condition when a detected workload of a memory interface of the SDRAM system satisfies at least one predetermined criterion; and
a memory physical module, coupled between the memory controller and the SDRAM device, and configured to process data signals and data strobe signals transmitted between the memory controller and the SDRAM device, the memory physical module comprising an interface timing calibration circuit configured to calibrate timing of data signals and data strobe signals of the SDRAM device by performing an interface timing training process according to a selected set of AC parameters and a selected set of interface timing parameters.

6. The memory system of claim 5, wherein the memory controller comprises a plurality of first registers configured to store a plurality of sets of AC parameters, and the memory physical module comprises a plurality of second registers configured to store a plurality of sets of interface timing parameters; and
wherein when the operation condition of the memory system is switched from the first condition to the second condition, the memory controller selects the selected set of AC parameters from the first registers and sends a selection signal to the memory physical module, and the memory physical module selects the selected set of interface timing parameters from the second registers according to the selection signal, such that the memory controller operates according to the selected set of AC parameters and the memory physical module operates according to the selected set of interface timing parameters.

7. The memory system of claim 6, further comprising:
a loading monitoring unit, configured to detect workload of the memory interface and generate the selection signal according to the detected workload of the memory interface.

8. The memory system of claim 5, further comprising:
a clock generator, coupled to the memory controller and configured to generate a plurality of reference clocks with different frequencies, and to select an operating clock for the memory system according to a selection signal;
wherein when the operation condition of the memory system is switched from the first condition to the second condition, a frequency of the operating clock is switched from a first frequency to a second frequency.

9. The memory system of claim 8, further comprising:
a loading monitoring unit, configured to detect workload of the memory interface and generate the selection signal according to the detected workload of the memory interface.

10. The memory system of claim 5, further comprising:
a voltage control unit, coupled to the memory controller, the memory physical module and the memory interface, and configured to determine voltage levels of an operation voltage and an SDRAM operating voltage according to selection signals;
wherein the operation voltage is applied to the memory controller and the memory physical module, and the SDRAM operating voltage is applied to the SDRAM device.

11. The memory system of claim 10, further comprising:
a loading monitoring unit, configured to detect the workload of the memory interface and generate the selection signals according to switch the operation mode of memory system.

12. A control method of a memory system, comprising:
performing a plurality of trimming procedures of a memory physical module of the memory system according to sets of AC parameters to generate a plurality of sets of interface timing parameters;
detecting workload of a memory interface of the memory system; and
switching an operation condition of the memory system from a first condition to a second condition when the detected workload of the memory interface satisfies at least one predetermined criterion;
wherein when the memory system operates in the first condition, the memory system is set according to a first set of the sets of the AC parameters and a first set of the sets of the interface timing parameters; and
wherein when the memory system operates in the second condition, the memory system is set according to a second set of the sets of the AC parameters and a second set of the sets of the interface timing parameters.

13. The control method of claim 12, further comprising:
performing a power-up initialization procedure to initialize the SDRAM device before performing each of the trimming procedures; and
adjusting settings of a frequency of an operating clock of the memory system, a voltage level of an operation voltage of a memory controller and a memory physical module of the memory system, and/or a voltage level of an SDRAM operating voltage of the SDRAM device before performing each power-up initialization procedure.

14. The control method of claim 13, further comprising:
selecting one of the sets of AC parameters from a plurality of first registers before performing each of the trimming procedures according to the selected set of AC parameters;
storing the sets of interface timing parameters in a plurality of second registers before detecting the workload of the memory interface; and
selecting the second set of the AC parameters from the first registers and selecting the second set of the interface timing parameters from the second registers after switching the operation condition of the SDRAM device from the first condition to the second condition.

15. The control method of claim 12, wherein switching the operation condition of the memory system from the first condition to the second condition comprises switching an operating frequency of the memory system from a first frequency to a second frequency.

16. The control method of claim 12, wherein switching the operation condition of the memory system from the first condition to the second condition comprises switching an operation voltage of the memory controller and memory physical module from a first voltage to a second voltage and/or switching an SDRAM operating voltage of the SDRAM device from a third voltage to a fourth voltage.
